(19) United States
(12) Patent Application Publication
(10) Pub. No.: US 2026/0351827 A1
(43) Pub. Date: Nov. 5, 2026

(54) SUBSTRATE

(71) Applicant: Panasonic Intellectual Property Management Co., Ltd., Osaka (JP)

(72) Inventor: YASUHIRO KAIZAKI, Kyoto (JP)

(21) Appl. No.: 19/484,524

(22) PCT Filed: Apr. 24, 2024
(86) PCT No.: PCT/JP2024/016050

§ 371 Date: Nov. 14, 2025

(30) Foreign Application Priority Data
Jun. 7, 2023 (JP) 2023-093783

(51) Int. Cl. H01P 1/36; H05K 1/02

(52) U.S. Cl. CPC H01P 1/36; H05K 1/0237

(57) ABSTRACT

A substrate is a substrate on which a digital isolator is to be mounted to electrically isolate first voltage region (R1) and second voltage region (R2) from each other in a plan view. The substrate includes: core layer (101); first ground layer (121) and second ground layer (122) on a first principal surface of core layer (101); first power supply layer (131) and second power supply layer (132) on a second principal surface of core layer (101); two planar patterns (123, 133) at least partially overlapping each other in the plan view; and linear pattern (124), in which a resonance frequency of a resonance circuit including two planar patterns (123, 133) and linear pattern (124) has a value corresponding to signal transmission by the digital isolator.

### TECHNICAL FIELD

The present disclosure relates to a substrate on which a digital isolator is to be mounted.

### BACKGROUND ART

There is technique of forming a stacked substrate by stacking a plurality of conductor patterns (see PTL 1). In such a stacked substrate, in a case where a portion operating at high voltage coexists with a portion operating at a low voltage in the same substrate, or in case where there is a risk that high voltage and large current may be applied to a low-voltage device depending on a use environment, there is a risk that the low-voltage circuit may be damaged by application of high voltage, or an electric shock may occur. In addition, when a state in which the GND potentials are different between the two points occurs, a path through which current flows from one GND to the other GND is generated. When current flows through this GND loop, a circuit or a device may fail or be damaged, which may cause noise generation or amplification. As a countermeasure against these problems, it is necessary to perform electrical separation, that is, insulation so that no current flows between two points of the electric circuit.

As a conventional insulating element, an optical isolator in which a light emitting element (for example, a light emitting diode (LED)) and a light receiving element are combined has been the mainstream, but there are problems of product life and reliability, and the optical isolator is shifting to a digital isolator (see PTL 2).

In a digital isolator, there are a magnetic coupling method and a capacitive coupling method depending on a method of transmitting a signal in an insulating region (See PTL 3 and PTL 4).

### CITATION LIST

### Patent Literature

PTL 1: Publication of Japanese Patent No. 5768941

PTL 2: Unexamined Japanese Patent Publication No.2018-011173

PTL 3: Specification of U.S. Pat. No. 6,054,780

PTL 4: Unexamined Japanese Patent Publication (Translation of PCT Application) No. 2020-515192

### SUMMARY OF THE INVENTION

In the technique of each patent literature, electro magnetic interference (EMI) called emission may be caused.

A substrate according to one aspect of the present disclosure is a substrate including a first voltage region and a second voltage region in a plan view, and on which a digital isolator is to be mounted to electrically isolate the first voltage region and the second voltage region is from each other, the substrate includes: a core layer; a first ground layer that is a conductor and is provided on a first principal surface of the core layer in the first voltage region; a second ground layer that is a conductor and is provided on the first principal surface of the core layer in the second voltage region; a first power supply layer provided on a second principal surface of the core layer in the first voltage region; a second power supply layer provided on the second principal surface of the core layer in the second voltage region; a plurality of planar patterns that are conductors and include two planar patterns at least partially overlapping each other in the plan view of the substrate; and a linear pattern that is linear in the plan view, in which the linear pattern is provided on a path connecting one of the first ground layer and the first power supply layer and one of the second ground layer and the second power supply layer, the linear pattern is connected to one of the two planar patterns, and a resonance frequency of a resonance circuit including the two planar patterns and the linear pattern has a value corresponding to signal transmission by the digital isolator.

According to one aspect of the present disclosure, in a substrate on which a digital isolator is to be mounted, it is possible to realize the substrate capable of suppressing occurrence of the electro magnetic interference.

### BRIEF DESCRIPTION OF THE DRAWINGS

FIG. 1 is a schematic view illustrating a signal path of an insulating element.

FIG. 2 is a cross-sectional view of a multilayer substrate of a conventional example.

FIG. 3 is a schematic perspective view illustrating a layer configuration of the multilayer substrate according to a first exemplary embodiment.

FIG. 4 is a view illustrating a configuration of the multilayer substrate according to the first exemplary embodiment.

FIG. 5 is a view illustrating an example of propagation characteristics of a common mode current of a stacked substrate according to the first exemplary embodiment.

FIG. 6 is a view illustrating a configuration of the multilayer substrate according to a second exemplary embodiment.

FIG. 7 is a view illustrating a configuration of the multilayer substrate according to a third exemplary embodiment.

FIG. 8 is a view illustrating a configuration of a double-sided substrate according to a fourth exemplary embodiment.

### DESCRIPTION OF EMBODIMENT

### Background to Present Disclosure

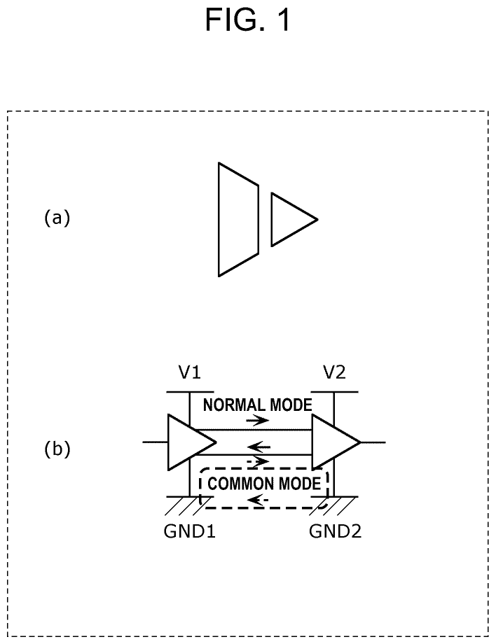

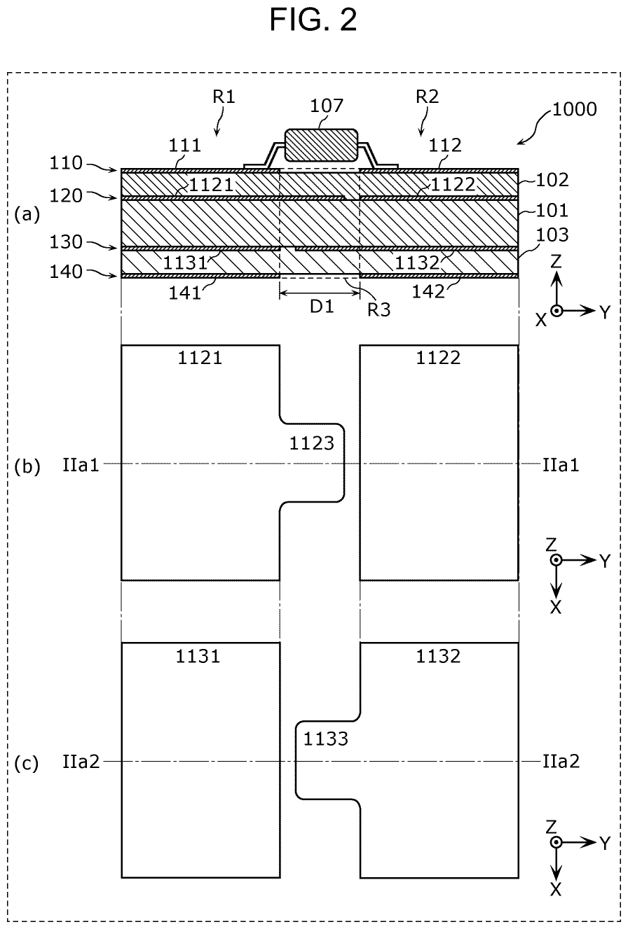

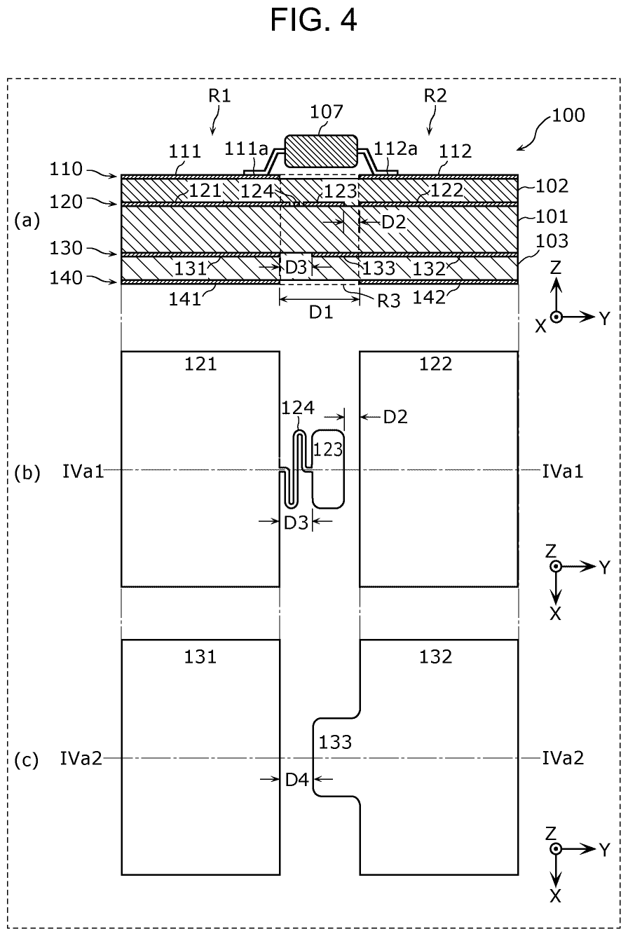

Prior to the description of the present disclosure, the background to the present disclosure will be described with reference to FIGS. 1 and 2. FIG. 1 is a schematic view illustrating a signal path of an insulating element. Part (a) of FIG. 1 is a circuit image view in a case where the insulation system is a magnetic system, and is illustrated for reference. Part (b) of FIG. 1 illustrates a signal path of the insulating element. FIG. 2 is a cross-sectional view of multilayer substrate 1000 of a conventional example. Part (a) of FIG. 2 is a cross-sectional view of multilayer substrate 1000, part (b) of FIG. 2 is a plan view illustrating second conductor layer 120, and part (c) of FIG. 2 is a plan view illustrating third conductor layer 130. A cross-sectional view of second conductor layer 120 illustrated in part (a) of FIG. 2 is a cross-sectional view of a case where second conductor layer 120 is cut along cutting line IIa1-IIa1 illustrated in part (b) of FIG. 2, and a cross-sectional view of third conductor layer 130 illustrated in part (a) of FIG. 2 is a cross-sectional view of a case where third conductor layer 130 is cut along cutting line IIa2-IIa2 illustrated in part (c) of FIG. 2. Note that cutting line IIa1-IIa1 and cutting line IIa2-IIa2 overlap each other in plan view. In addition, in FIGS. 4 and 6 to 8 described below, the relationship between the cross-sectional views of second conductor layer 120 and third conductor layer 130 illustrated in parts (a) of FIGS. 4 and 6 to 8 and the cutting lines illustrated in parts (b) and (c) of FIGS. 4 and 6 to 8 is similar to that in FIG. 2, and thus the description thereof is omitted.

Note that the layer configuration and the like of multilayer substrate 1000 will be described in the exemplary embodiment.

As illustrated in part (b) of FIG. 1, a digital isolator basically exchanges signals using a high-frequency digital signal on a differential transmission path formed by a transformer or capacitance between regions (a region of V1, which is first voltage region R1 illustrated in part (a) of FIG. 2 and a region of V2, which is second voltage region R2 illustrated in part (a) of FIG. 2) having different potentials with insulating region R3 (see part (a) of FIG. 2) interposed therebetween. At this time, a common mode current is generated in addition to a normal mode signal on the differential transmission path. This common mode current becomes a leakage current (stray current), but since the digital isolator has an insulating region, there is a possibility that the leakage current cannot be fed back from the voltage region of the propagation destination to the voltage region of the signal source. The emission of the digital isolator is a phenomenon in which a leakage current that cannot be fed back diffuses as radiation noise (emission) from the end portion of the insulating region. The ground in first voltage region R1 is illustrated as GND1, and the ground in second voltage region R2 is illustrated as GND2.

In order to reduce occurrence of the emission due to the leakage current, it is only required to secure a path for feeding back current across barriers of different voltage regions.

One method is a method of connecting a capacitor of a safe rating across the barriers of different voltage regions, and another method is a method of forming a capacitor in which a ground plane and a power plane of internal layers of a stacked substrate are extended to insulating region R3 of the stacked substrate and overlapped. The capacitor is formed of planar pattern 1123 connected to first ground layer 1121 and planar pattern 1133 connected to second power supply layer 1132. Note that the capacitor may be formed of a planar pattern connected to second ground layer 1122 and a planar pattern connected to first power supply layer 1131.

Among the two methods, the method of connecting a capacitor has problems that it is difficult to cope with a high-frequency carrier wave due to the influence of parasitic inductance of the capacitor, and that a loop area of a common mode current formed by an arrangement place of the capacitor and the insulating element increases. In general, the emission is proportional to the magnitude and area of the current flowing through the loop, so that the emission increases as the loop area increases. In addition, in the method of forming a capacitor in the internal layers, it is known that the capacitor capacitance to be formed depends on the thickness of the substrate, and the thickness of the substrate is restricted in the corresponding insulation standard. For example, in IEC62368 (formerly IEC60950) which is a representative insulation standard, the thickness of a single layer between conductors having different potentials is designated as 0.4 mm or more. Therefore, there is a problem that the pass characteristics (frequency characteristics) of the signal obtained by forming an inner layer capacitor do not match the frequency of the carrier wave used in the insulating element.

Therefore, the inventor of the present application has intensively studied a substrate (substrate structure) capable of efficiently feeding back a common mode current of digital isolation as a substrate capable of suppressing occurrence of the electro magnetic interference in a substrate on which a digital isolator is to be mounted, and has invented a substrate described below.

An exemplary embodiment will be specifically described hereinafter with reference to the drawings.

The exemplary embodiments described below illustrate comprehensive or specific examples. Numerical values, shapes, constituent elements, disposition positions and connection forms of the constituent elements, and the like described in the following exemplary embodiments are illustrative, and are not intended to limit the scope of the present disclosure. Moreover, among the constituent elements in the following exemplary embodiments, constituent elements not recited in the independent claims are described as arbitrary constituent elements.

In addition, each of the drawings is a schematic view, and is not necessarily strictly illustrated. Therefore, for example, scales and the like are not necessarily matched in the respective drawings. In addition, in each drawing, substantially identical components are denoted by identical reference signs, and the redundant description will be omitted or simplified.

In addition, in the present specification and the drawings, an X-axis, a Y-axis, and a Z-axis indicate three axes of a right-handed type three-dimensional orthogonal coordinate system. In each exemplary embodiment, the Z-axis direction is a stacking direction (thickness direction) of the multilayer substrate. In addition, in the present specification, “plan view” means that the multilayer substrate is viewed along the stacking direction of the multilayer substrate.

In addition, in the present specification, terms indicating a relationship between elements such as parallel and coincidence, terms indicating the shape of elements such as linear and meander shape, numerical values, and numerical ranges are not expressions representing only strict meanings, but are expressions meaning to include substantially equivalent ranges, for example, differences of about several % (alternatively, about 10%).

In addition, in the present specification, the terms “on XX (for example, on principal surface)”, “upward”, and “downward” do not refer to an upward direction (vertically upward) and a downward direction (vertically downward) in absolute space recognition, but are used as terms defined by a relative positional relationship on the basis of a stacking order in a stacking configuration. Also, the terms “on XX (for example, on principal surface)”, “upward”, and “downward” apply not only when two constituent elements are arranged with a space apart from each other and there is another constituent element between the two constituent elements, but also when the two constituent elements are arranged in contact with each other.

In addition, in the present specification, ordinal numbers such as “first” and “second” do not mean the number or order of constituent elements unless otherwise specified, and are used for the purpose of avoiding confusion and distinguishing the same kind of constituent elements.

In addition, “connection” of each constituent element means electrical connection, and includes not only a case where two constituent elements are directly connected but also a case where two constituent elements are indirectly connected in a state where another constituent element is inserted between the two constituent elements.

### First Exemplary Embodiment

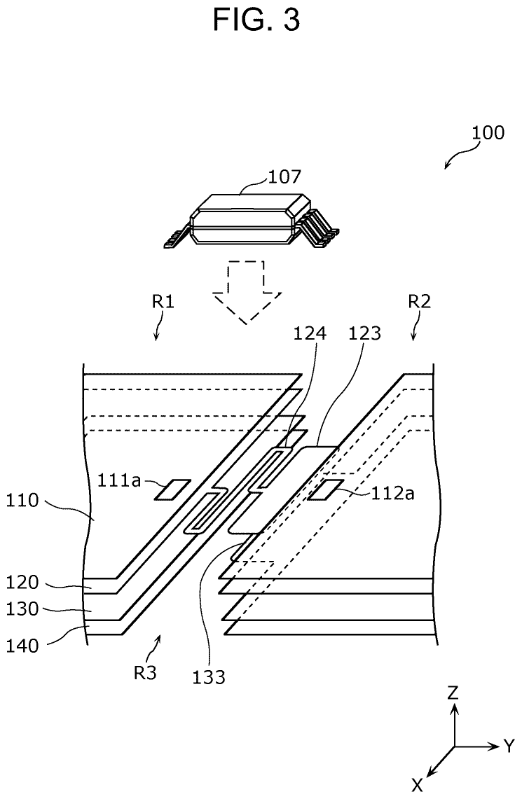

Hereinafter, a multilayer substrate according to the present exemplary embodiment will be described with reference to FIGS. 3 to 5.

### [1. Configuration of Multilayer Substrate]

FIG. 3 is a schematic perspective view illustrating a layer configuration of multilayer substrate 100 according to the present exemplary embodiment. FIG. 4 is a view illustrating a configuration of multilayer substrate 100 according to the present exemplary embodiment. Part (a) of FIG. 4 is a cross-sectional view of multilayer substrate 100, part (b) of FIG. 4 is a plan view illustrating second conductor layer 120, and part (c) of FIG. 4 is a plan view illustrating third conductor layer 130.

In FIG. 3, each conductor layer and insulating device 107 are illustrated, and illustrations of other constituent elements are omitted for convenience. In addition, FIG. 3 illustrates a state in which insulating device 107 is not mounted on multilayer substrate 100, and FIG. 4 illustrates a state in which insulating device 107 is mounted on multilayer substrate 100. In addition, in the present exemplary embodiment, an example in which a four-layer substrate is used as representative multilayer substrate 100 will be described.

Multilayer substrate 100 on which insulating device 107 is mounted is used to suppress damage and the like due to application of high voltage to a portion operating at low voltage in a device or the like in which a portion (circuit) operating at high voltage coexists with a portion (circuit) operating at low voltage. Examples of the device include industrial devices such as a power supply and a motor, medical devices, and in-vehicle devices such as an electronic control unit (ECU) mounted on a hybrid vehicle, but are not limited thereto.

As illustrated in FIGS. 3 and 4, multilayer substrate 100 includes first voltage region R1 and second voltage region R2, which are different voltage regions, and insulating region R3 between first voltage region R1 and second voltage region R2. A region closer to a Y-axis minus side than insulating region R3 (three-dimensional region) is first voltage region R1 (three-dimensional region), and a region closer to a Y-axis plus side than insulating region R3 is second voltage region R2 (three-dimensional region).

In addition, multilayer substrate 100 includes core layer 101, first insulating layer 102, second insulating layer 103, and insulating device 107. In multilayer substrate 100, second insulating layer 103, core layer 101, and first insulating layer 102 are stacked in this order, and insulating device 107 is mounted above first insulating layer 102. Multilayer substrate 100 is an example of a substrate.

Core layer 101 is an insulating substrate included in multilayer substrate 100, and is, for example, a resin substrate. Core layer 101 may be formed of, for example, materials corresponding to FR-4 (flame retardant type 4) which is a substrate material. Core layer 101 may be, for example, a glass epoxy substrate, but is not limited thereto. Core layer 101 is a double-sided substrate in which conductor layers (second conductor layer 120 and third conductor layer 130) are provided on both surfaces of core layer 101.

First insulating layer 102 is a layer having an insulating property provided by being stacked on the upper surface (a first principal surface on the Z-axis plus side) of core layer 101. First conductor layer 110 is provided on the upper surface of first insulating layer 102.

Second insulating layer 103 is a layer provided by being stacked on the lower surface (a second principal surface on the Z-axis minus side) of core layer 101 and having an insulating property. Fourth conductor layer 140 is provided on a lower surface of second insulating layer 103.

First insulating layer 102 and second insulating layer 103 are also referred to as prepreg layers, and are configured to contain, for example, an epoxy resin, but are not limited thereto. In addition, first insulating layer 102 and second insulating layer 103 may contain carbon fiber and the like.

First conductor layer 110 is a layer that is provided on an upper surface (the surface on the Z-axis plus side) of first insulating layer 102 and is made of a metal material (for example, copper foil). First conductor layer 110 is provided with, for example, wiring for mounting a device (including insulating device 107, for example), a signal line, and the like. For example, a device is mounted on first conductor layer 110.

First conductor layer 110 includes first conductor pattern 111 provided in first voltage region R1 and second conductor pattern 112 provided in second voltage region R2. Third terminal 111a (conductor pattern) to which a terminal (first terminal) of insulating device 107 is connected is formed in first conductor pattern 111, and fourth terminal 112a (conductor pattern) to which a terminal (second terminal) of insulating device 107 is connected is formed in second conductor pattern 112.

First conductor pattern 111 and second conductor pattern 112 are provided at a distance D1, for example. The distance D1 is an insulating distance, and is a creepage distance determined by a potential difference between first voltage region R1 and second voltage region R2 and a corresponding insulation standard. In other words, multilayer substrate 100 has insulating region R3 having the distance D1.

Second conductor layer 120 is a layer that is provided between core layer 101 and first insulating layer 102, and is made of a metal material (for example, copper foil). Second conductor layer 120 is provided with, for example, a ground layer.

Second conductor layer 120 includes first ground layer 121 provided in first voltage region R1 and second ground layer 122 provided in second voltage region R2.

Third conductor layer 130 is a layer that is provided between core layer 101 and second insulating layer 103, and is made of a metal material (for example, copper foil). Third conductor layer 130 is provided with, for example, a power supply layer.

Third conductor layer 130 includes first power supply layer 131 provided in first voltage region R1 and second power supply layer 132 provided in second voltage region R2.

Fourth conductor layer 140 is a layer that is provided on a lower surface (the surface on the Z-axis minus side) of second insulating layer 103 and is made of a metal material (for example, copper foil). Fourth conductor layer 140 is provided with, for example, wiring for mounting a device, a signal line, and the like. For example, a device is mounted on fourth conductor layer 140.

Fourth conductor layer 140 includes first conductor pattern 141 provided in first voltage region R1 and second conductor pattern 142 provided in second voltage region R2. First conductor pattern 141 and second conductor pattern 142 are provided at the distance D1, for example.

Insulating device 107 is an insulating amplifier provided between regions having different voltage regions, and is a device that exchanges signals between the different voltage regions using a carrier wave in a state where the different voltage regions are electrically insulated from each other. Insulating device 107 is also referred to as a digital isolator. The signal transmission method of insulating region R3 in insulating device 107 may be a magnetic coupling method or a capacitive coupling method. In addition, insulating device 107 is provided so as to straddle insulating region R3. Note that the frequency of the carrier wave of insulating device 107 is, for example, 480 MHz, but may be lower than 480 MHz such as 180 MHz or higher than 480 MHz.

Here, a feedback path of a common mode current, which is a main part of the present application, will be described.

Multilayer substrate 100 according to the present exemplary embodiment further includes planar pattern 123 and linear pattern 124 in second conductor layer 120 and planar pattern 133 in third conductor layer 130 in order to form the feedback path of the common mode current.

Planar patterns 123 and 133 are provided so as to at least partially overlap each other in plan view. In the example of FIG. 4, planar pattern 133 is provided so as to cover entire planar pattern 123 in plan view.

Planar pattern 123 is provided, for example, in insulating region R3 of second conductor layer 120 so as to be separated from each of first ground layer 121 and second ground layer 122 in plan view. For example, planar pattern 123 is provided in insulating region R3 so as to be separated from second ground layer 122 at a distance D2 in plan view. Planar pattern 123 is connected to first ground layer 121 via linear pattern 124.

For example, planar pattern 133 is provided in insulating region R3 of third conductor layer 130 so as to protrude toward first power supply layer 131 from the side surface of second power supply layer 132 on the side of first power supply layer 131 (the surface on the Y-axis minus side) in plan view. For example, planar pattern 133 is provided in insulating region R3 so as to be separated from first power supply layer 131 at a distance D4 in plan view. The distance D4 may be equal to or smaller than a distance D3. For example, at least a part of planar pattern 133 may overlap linear pattern 124 in plan view.

Linear pattern 124 is a conductor pattern for forming an inductor, and is provided on a path (feedback path) between one of first ground layer 121 and first power supply layer 131 and one of second ground layer 122 and second power supply layer 132. In the example of FIG. 4, linear pattern 124 connects first ground layer 121 and planar pattern 123 on the path. The length of linear pattern 124 in the Y-axis direction is, for example, the distance D3. In addition, in the example of FIG. 4, the planar view shape of linear pattern 124 is a meander shape, but the shape is not limited thereto, and may be, for example, a linear shape. In addition, linear pattern 124 may have, for example, a spiral shape or the like formed in another layer via a through hole or the like as long as the regulation of the insulation distance is satisfied.

In the present exemplary embodiment, from the viewpoint of further suppressing occurrence of electro magnetic interference, planar patterns 123 and 133 and linear pattern 124 are provided at positions overlapping insulating device 107 in plan view, but the present invention is not limited thereto.

Note that the distances D1 to D4 described above are distances (insulation distances) in a direction parallel to the Y-axis. Each of the distances D1 to D4 is set to a distance or more satisfying the corresponding insulation standard.

As described above, in the present exemplary embodiment, an inductor is formed by linear pattern 124, capacitance is formed by a capacitor (parallel plate capacitor) by planar patterns 123 and 133, and an LC resonance circuit (LC series resonance circuit) is formed between first voltage region R1 and second voltage region R2.

As a result, since the pass band of the signal can be adjusted by the inductor and the capacitance, the frequency can be adjusted in a wide range as compared with the case where the pass band is adjusted only by the capacitance as illustrated in FIG. 2. Therefore, since the common mode current can be more reliably fed back to the signal source, according to multilayer substrate 100, the possibility of causing electro magnetic interference can be reduced.

Note that the resonance frequency of the LC resonance circuit has a value corresponding to signal transmission by insulating device 107. For example, the resonance frequency of the LC resonance circuit is set to allow passage of a signal having a frequency of a carrier wave used in insulating device 107. For example, the resonance frequency of the LC resonance circuit is set to match the frequency of the carrier wave used in insulating device 107.

Note that the configuration forming the feedback path of the common mode current is not limited to the configuration illustrated in FIG. 4. For example, the conductor patterns of second conductor layer 120 and third conductor layer 130 in insulating region R3 may be interchanged. For example, a planar pattern may be provided so as to protrude from a side surface of second ground layer 122 on first ground layer 121 side (the surface on the Y-axis minus side) toward first ground layer 121 side, a planar pattern overlapping the planar pattern in plan view may be formed on third conductor layer 130, and the planar pattern of third conductor layer 130 may be connected to first power supply layer 131 by a linear pattern. In addition, for example, linear pattern 124 may connect planar pattern 123 and second ground layer 122 and a planar pattern may be provided so as to protrude toward second power supply layer 132 side from a side surface of first power supply layer 131 on the second power supply layer 132 side (the surface on the Y-axis plus side). In addition, for example, planar pattern 133 may be provided in insulating region R3 of third conductor layer 130 so as to be separated from each of first power supply layer 131 and second power supply layer 132 in plan view, and may be connected to second power supply layer 132 via a linear pattern. That is, the linear pattern may be provided in at least one of second conductor layer 120 and third conductor layer 130.

### [2. Propagation Characteristics of Multilayer Substrate]

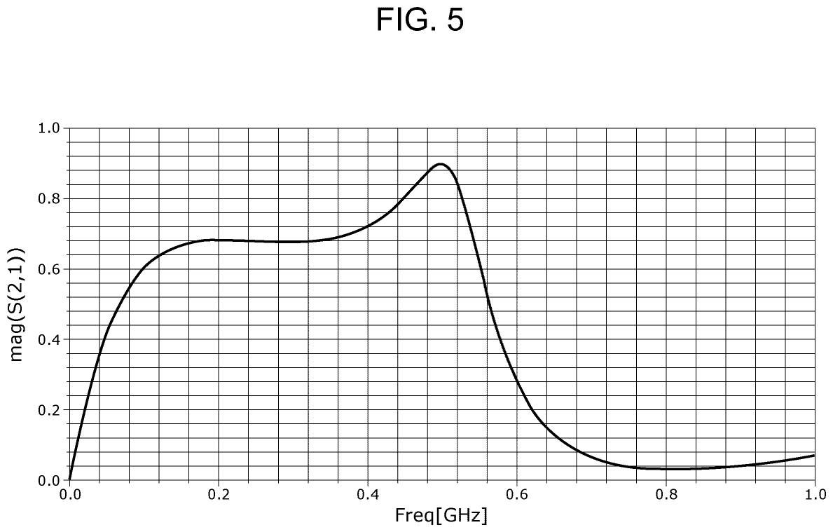

The propagation characteristics of the common mode current in multilayer substrate 100 configured as described above will be described with reference to FIG. 5. FIG. 5 is a view illustrating an example of propagation characteristics of a common mode current of multilayer substrate 100 according to the present exemplary embodiment.

Multilayer substrate 100 is assumed to be applied to FR-4 which is a representative substrate material. In addition, the thickness (length in the Z-axis direction) of core layer 101 of multilayer substrate 100 is assumed to be 0.6 mm, and the thicknesses of first insulating layer 102 and second insulating layer 103 are assumed to be 0.3 mm.

As illustrated in FIG. 5, multilayer substrate 100 having such a configuration has pass characteristics around 480 MHz that is difficult only with a capacitor. In other words, multilayer substrate 100 has propagation characteristics that allow a signal of 480 MHz, which is the frequency of the carrier wave of insulating device 107, to pass therethrough.

By adjusting the shapes of planar patterns 123 and 133 and linear pattern 124 according to the frequency of the carrier wave to be passed, it is possible to create a path (feedback path of the common mode current) through which a signal (for example, common mode current) can easily pass from one of first voltage region R1 and second voltage region R2 to the other in the band of the carrier wave of insulating device 107.

As described above, in multilayer substrate 100, by adjusting the series resonance frequency of the capacitor and the inductor, it is possible to allow the passage of a signal in a high frequency band such as 480 MHz that is difficult to realize only by the capacitor.

Note that the resonance frequency of the LC resonance circuit may be set to match the frequency of the carrier wave, or may be set such that a difference from the frequency of the carrier wave is less than or equal to a predetermined frequency, for example. As described above, the resonance frequency of the LC resonance circuit has a value corresponding to signal transmission by digital isolation, and the capacitance value and the inductor value are determined so that the value can be realized.

### Second Exemplary Embodiment

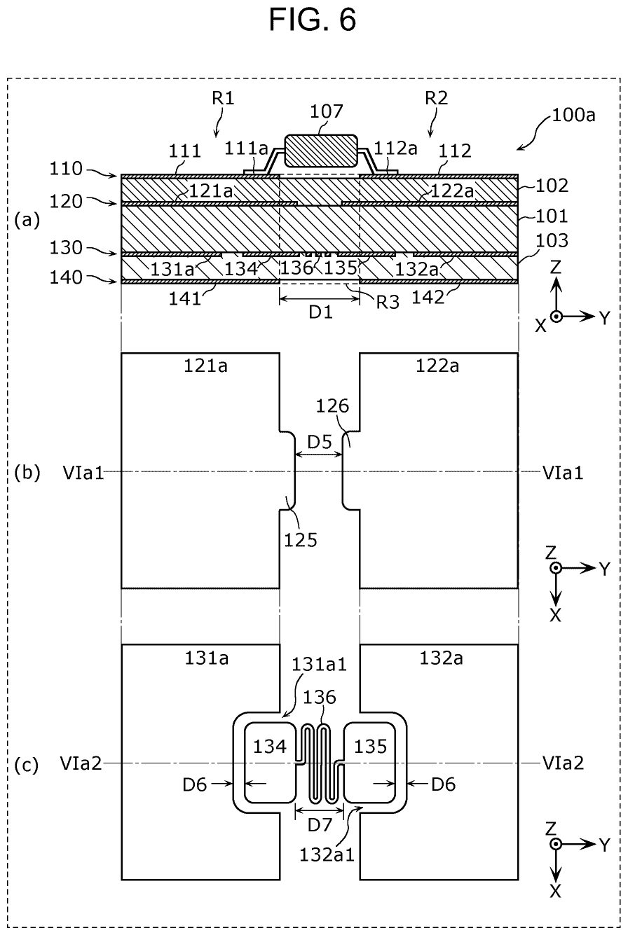

Hereinafter, a multilayer substrate according to the present exemplary embodiment will be described with reference to FIG. 6. Hereinafter, differences from the first exemplary embodiment will be mainly described, and the description of the contents same as or similar to those of the first exemplary embodiment will be omitted or simplified.

FIG. 6 is a view illustrating a configuration of multilayer substrate 100a according to the present exemplary embodiment. Part (a) of FIG. 6 is a cross-sectional view of multilayer substrate 100a, part (b) of FIG. 6 is a plan view illustrating second conductor layer 120, and part (c) of FIG. 6 is a plan view illustrating third conductor layer 130. Multilayer substrate 100a according to the present exemplary embodiment is different from multilayer substrate 100 according to the first exemplary embodiment mainly in that two capacitors are formed. Multilayer substrate 100a is an example of a substrate. Hereinafter, a distance D7 is less than or equal to the distance D1.

As illustrated in FIG. 6, second conductor layer 120 includes planar patterns 125 and 126.

Planar pattern 125 is a planar conductor pattern formed so as to protrude toward second ground layer 122a from the surface on second ground layer 122a side (the surface on the Y-axis plus side) of first ground layer 121a. Planar pattern 126 is a planar conductor pattern formed so as to protrude toward first ground layer 121a side from the surface on first ground layer 121a side (the surface on the Y-axis minus side) of second ground layer 122a. Planar patterns 125 and 126 are provided at positions separated at a distance D5 (insulation distance).

At least one of planar patterns 125 and 126 may be connected to a conductor pattern via a linear pattern. For example, planar pattern 125 may be connected to first ground layer 121a via a linear pattern.

Third conductor layer 130 has planar patterns 134 and 135 and linear pattern 136.

Planar patterns 134 and 135 are provided in insulating region R3 to be separated from each of first power supply layer 131a and second power supply layer 132a in plan view, and are connected by linear pattern 136.

Planar pattern 134 is a conductor pattern for forming a capacitor using planar pattern 125 and a part of first ground layer 121a. In first power supply layer 131a, recess 131al recessed in a U shape in the Y-axis minus direction from the surface on the Y-axis plus side is formed, and at least a part of planar pattern 134 is provided in recess 131a1 such that the distance between the part of planar pattern 134 and first power supply layer 131a becomes a distance D6. In other words, planar pattern 134 is provided so as to overlap each of a part of first ground layer 121a and planar pattern 125 in plan view. Planar pattern 134 is only required to overlap at least planar pattern 125 in plan view.

Planar pattern 135 is a conductor pattern for forming a capacitor using planar pattern 126 and a part of second ground layer 122a. In second power supply layer 132a, recess 132al recessed in a U shape in the Y-axis plus direction from the surface on the Y-axis minus side is formed, and at least a part of planar pattern 135 is provided in recess 132al such that the distance between the part of planar pattern 135 and second power supply layer 132a becomes the distance D6. In other words, planar pattern 135 is provided so as to overlap each of a part of second ground layer 122a and planar pattern 126 in plan view. Planar pattern 135 is only required to overlap at least planar pattern 126 in plan view.

Linear pattern 136 is a pattern for forming an inductor, and is provided between planar patterns 134 and 135 in plan view and connects planar patterns 134 and 135 in the example of FIG. 6. The length of linear pattern 136 in the Y-axis direction is, for example, the distance D7. The distance D7 may be, for example, a distance equal to the distance D5.

As described above, multilayer substrate 100a has planar pattern 134 in insulating region R3 on first voltage region R1 side of third conductor layer 130, planar pattern 135 on second voltage region R2 side, and a configuration in which planar patterns 134 and 135 are electrically connected by meander-shaped linear pattern 136.

As a result, the LC resonance circuit can be formed between first voltage region R1 and second voltage region R2. By adjusting the shape of at least one of planar patterns 125, 126, 134, and 135 and linear pattern 136, it is possible to create a path (feedback path of common mode current) through which a signal easily passes between first voltage region R1 and second voltage region R2 according to the band of the carrier wave of insulating device 107. In addition, since there are two pieces of capacitance in the path through which the leakage current passes, it is possible to function as double insulation, and improve the voltage resistance of multilayer substrate 100a. Such multilayer substrate 100a can correspond to an application requiring a high withstand voltage.

Although the areas of planar patterns 134 and 135 are the same in plan view, the areas may be different from each other, for example.

Note that planar patterns 125 and 126 are not required to be provided as long as a desired capacitance can be obtained.

Note that the conductor patterns of second conductor layer 120 and third conductor layer 130 may be interchanged. For example, planar patterns 134 and 135 and linear pattern 136 may be formed in second conductor layer 120, and planar patterns 125 and 126 may be formed in third conductor layer 130.

Note that the above distances D5 to D7 are distances (insulation distances) in a direction parallel to the Y-axis. Each of the distances D5 to D7 is set to a distance or more satisfying the corresponding insulation standard. For example, the distance D6 is set to a distance or more satisfying the corresponding insulation standard at a voltage of ½ of the rated voltage of insulating device 107.

### Third Exemplary Embodiment

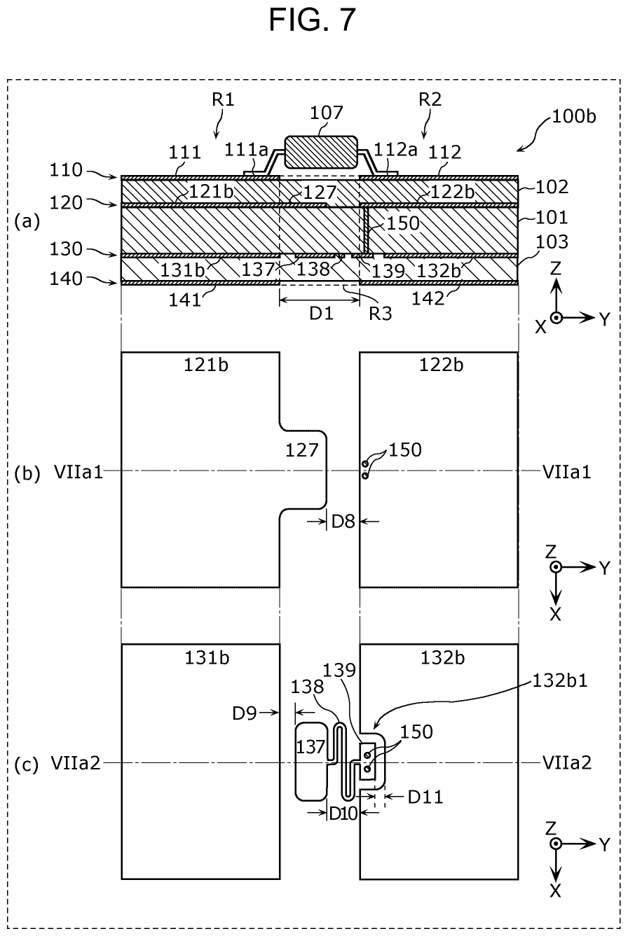

Hereinafter, a multilayer substrate according to the present exemplary embodiment will be described with reference to FIG. 7. Hereinafter, differences from the first exemplary embodiment will be mainly described, and the description of the contents same as or similar to those of the first exemplary embodiment will be omitted or simplified.

FIG. 7 is a view illustrating a configuration of multilayer substrate 100b according to the present exemplary embodiment. Part (a) of FIG. 7 is a cross-sectional view of multilayer substrate 100b, part (b) of FIG. 7 is a plan view illustrating second conductor layer 120, and part (c) of FIG. 7 is a plan view illustrating third conductor layer 130. Multilayer substrate 100b according to the present exemplary embodiment is different from multilayer substrate 100 according to the first exemplary embodiment in that a capacitor is formed of conductor patterns (planar patterns 127 and 137) connected to a ground layer. Multilayer substrate 100b is an example of a substrate.

Multilayer substrate 100b according to the present exemplary embodiment has planar pattern 127 in second conductor layer 120 and planar pattern 137, linear pattern 138, and land 139 in third conductor layer 130 in order to form a feedback path of a common mode current. In addition, multilayer substrate 100b has through hole 150 penetrating core layer 101 in second voltage region R2.

Planar patterns 127 and 137 are provided so as to at least partially overlap each other in plan view. In the example of FIG. 7, planar pattern 127 is provided so as to cover entire planar pattern 137 in plan view.

For example, in insulating region R3 of second conductor layer 120, planar pattern 127 is provided so as to protrude toward second ground layer 122b side from the side surface of first ground layer 121b on second ground layer 122b side (the surface on the Y-axis plus side). For example, planar pattern 127 is provided in insulating region R3 so as to be separated from second ground layer 122b at a distance D8 in plan view. For example, at least a part of planar pattern 127 may overlap linear pattern 138 in plan view.

Planar pattern 137 is provided to be separated from each of first power supply layer 131b and second power supply layer 132b in plan view. For example, planar pattern 137 is provided in insulating region R3 so as to be separated from first power supply layer 131b at a distance D9 in plan view. Planar pattern 137 is connected to second ground layer 122b via linear pattern 138, land 139, and through hole 150.

Linear pattern 138 is a pattern for forming an inductor, and connects planar pattern 137 and land 139 in the example of FIG. 7. The length of linear pattern 138 in the Y-axis direction is, for example, a distance D10.

Land 139 is a conductor pattern electrically connected to through hole 150. In second power supply layer 132b, recess 132b1 recessed in a U shape in the Y-axis plus direction from the surface on the Y-axis minus side is formed, and at least a part of land 139 is provided in recess 132b1 so that the distance between land 139 and second power supply layer 132b becomes a distance D11. In other words, land 139 is provided so as to overlap a part of second power supply layer 132b in plan view.

Through hole 150 penetrates core layer 101 of multilayer substrate 100 in the stacking direction (Z-axis direction) and connects land 139 and second ground layer 122b. That is, through hole 150 connects second ground layer 122b and planar pattern 137. As a result, second ground layer 122b and planar pattern 137 have the same potential.

Note that the above distances D8 to D11 are distances (insulation distances) in a direction parallel to the Y-axis. Each of the distances D8 to D11 is set to a distance or more satisfying the corresponding insulation standard.

As described above, in the present exemplary embodiment, an inductor is formed by linear pattern 138, capacitance is formed by capacitor by planar patterns 127 and 137, and an LC resonance circuit is formed between first voltage region R1 and second voltage region R2. By adjusting the shape of at least one of planar patterns 127 and 137 and linear pattern 138, it is possible to create a path (feedback path of common mode current) through which a signal easily passes between first voltage region R1 and second voltage region R2 according to the band of the carrier wave of insulating device 107. In the example of FIG. 7, a path through which a signal can pass can be formed between first ground layer 121b and second ground layer 122b.

Note that the conductor patterns of second conductor layer 120 and third conductor layer 130 in insulating region R3 may be interchanged. For example, planar pattern 137, linear pattern 138, and land 139 may be formed in second conductor layer 120, and planar pattern 127 may be formed in third conductor layer 130. In addition, land 139 and through hole 150 are not limited to being provided in second voltage region R2, but may be provided in first voltage region R1. In this case, for example, in insulating region R3 of second conductor layer 120, planar pattern 127 is provided so as to protrude toward first ground layer 121b side from the side surface (the surface on the Y-axis minus side) of second ground layer 122b on first ground layer 121b side.

### Fourth exemplary embodiment)

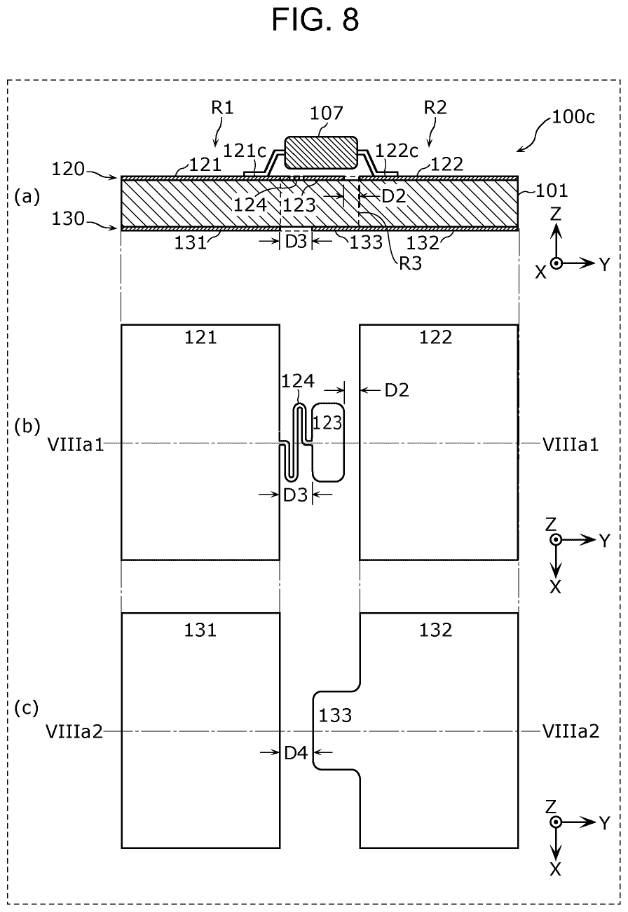

Hereinafter, a double-sided substrate according to the present exemplary embodiment will be described with reference to FIG. 8. Hereinafter, differences from the first exemplary embodiment will be mainly described, and the description of the contents same as or similar to those of the first exemplary embodiment will be omitted or simplified.

FIG. 8 is a view illustrating a configuration of double-sided substrate 100c according to the present exemplary embodiment. Part (a) of FIG. 8 is a cross-sectional view of double-sided substrate 100c, part (b) of FIG. 8 is a plan view illustrating second conductor layer 120, and part (c) of FIG. 8 is a plan view illustrating third conductor layer 130. Double-sided substrate 100c according to the present exemplary embodiment is different from multilayer substrate 100 according to the first exemplary embodiment in that double-sided substrate 100c does not include first insulating layer 102 and second insulating layer 103. Double-sided substrate 100c is also referred to as a two-layer substrate, and is an example of a substrate. Note that parts (b) and (c) of FIG. 8 are substantially the same as parts (b) and (c) of FIG. 4, and thus, description thereof is omitted. In addition, in parts (b) and (c) of FIG. 8, illustrations of third terminal 121c and fourth terminal 122c are omitted.

As illustrated in FIG. 8, double-sided substrate 100c includes core layer 101 and insulating device 107.

Core layer 101 includes second conductor layer 120 on the first principal surface (the surface on the Z-axis plus side), and third conductor layer 130 on the second principal surface (the surface on the Z-axis minus side).

Second conductor layer 120 includes first ground layer 121 provided in first voltage region R1 and second ground layer 122 provided in second voltage region R2. Third terminal 121c (conductor pattern) to which a terminal (first terminal) of insulating device 107 is connected is formed in first ground layer 121, and fourth terminal 122c (conductor pattern) to which a terminal (second terminal) of insulating device 107 is connected is formed in second ground layer 122. In addition, second conductor layer 120 may be provided with, for example, wiring for mounting a device (including insulating device 107, for example), a signal line, a ground layer, and the like in a mixed manner.

Third conductor layer 130 includes first power supply layer 131 provided in first voltage region R1 and second power supply layer 132 provided in second voltage region R2. Third conductor layer 130 may be provided with, for example, a power supply line, wiring for mounting a device, a signal line, and the like in a mixed manner.

### Other Exemplary Embodiments

Although the substrates according to one or a plurality of aspects have been described on the basis of each embodiment, the present disclosure is not limited to each embodiment. Configurations in which various variations conceived by those skilled in the art are applied to the present exemplary embodiments, and configurations established by combining constituent elements in different exemplary embodiments may also fall within the present disclosure, without departing from the gist of the present disclosure.

For example, the present disclosure may be realized as a designing method of a substrate on which a digital isolator is to be mounted. The designing method includes steps of: acquiring a frequency of a carrier wave used by a digital isolator to be mounted on a substrate; and determining shapes of a planar pattern and a linear pattern such that the acquired frequency of the carrier wave matches a resonance frequency of an LC series resonant circuit.

In addition, in each of the above exemplary embodiments, an example has been described in which first voltage region R1 and second voltage region R2 are regions having different voltages from each other, but the present invention is not limited thereto, and first voltage region R1 and second voltage region may be regions having the same potential.

In addition, second conductor layer 120 and third conductor layer 130 in the first exemplary embodiment may be interchanged. That is, first ground layer 121 and second ground layer 122 may be interchanged with first power supply layer 131 and second power supply layer 132. Each of first ground layer 121, second ground layer 122, first power supply layer 131, and second power supply layer 132 is a layer to which a DC potential is supplied. For example, whether second conductor layer 120 functions as a ground layer or a power supply layer is determined after various circuits and the like are mounted on multilayer substrate 100. The same applies to other exemplary embodiments.

In addition, in the first exemplary embodiment, an example has been described in which first ground layer 121 and second ground layer 122 are provided in second conductor layer 120, and first power supply layer 131 and second power supply layer 132 are provided in third conductor layer 130, but the present invention is not limited to thereto. First ground layer 121 and second ground layer 122, as well as first power supply layer 131 and second power supply layer 132, may each be provided in any one of first conductor layer 110, second conductor layer 120, third conductor layer 130, and fourth conductor layer 140.

In addition, in each of the above exemplary embodiments, an example has been described in which one or two planar patterns are provided on one principal surface of core layer 101, but the number of planar patterns is not limited thereto, and for example, three or more planar patterns may be provided on the one principal surface. Similarly, in the linear pattern, two or more linear patterns may be provided on the one principal surface.

In addition, in each of the above exemplary embodiments, a part or all parts of at least one of the planar pattern and the linear pattern may be provided at a position not overlapping insulating device 107 in plan view.

In addition, in each of the above exemplary embodiments, an example has been described in which the substrate is a two-layer substrate or a four-layer substrate, but the present invention is not limited thereto, and the substrate may be a three-layer substrate or a substrate having five or more layers.

In addition, the substrate in each of the above exemplary embodiments may be distributed in a state where insulating device 107 is not mounted, or may be distributed in a state where insulating device 107 is mounted.

### Supplementary Note

The following techniques are disclosed by the above description of each exemplary embodiment.

(Technique 1) A substrate including a first voltage region and a second voltage region in a plan view, and on which a digital isolator is to be mounted to electrically isolate the first voltage region and the second voltage region from each other, the substrate including: a core layer; a first ground layer that is a conductor and is provided on a first principal surface of the core layer in the first voltage region; a second ground layer that is a conductor and is provided on the first principal surface of the core layer in the second voltage region; a first power supply layer provided on a second principal surface of the core layer in the first voltage region; a second power supply layer provided on the second principal surface of the core layer in the second voltage region; a plurality of planar patterns that are conductors and include two planar patterns at least partially overlapping each other in the plan view of the substrate; and a linear pattern that is linear in the plan view, in which the linear pattern is provided on a path connecting one of the first ground layer and the first power supply layer and one of the second ground layer and the second power supply layer, the linear pattern is connected to one of the two planar patterns, and a resonance frequency of a resonance circuit including the two planar patterns and the linear pattern has a value corresponding to signal transmission by the digital isolator.

According to this, by adjusting the shapes of the planar pattern and the linear pattern, it is possible to create a path (a feedback path of a common mode current) through which a signal (for example, the common mode current) easily passes from one of the first voltage region and the second voltage region to the other in the band of the carrier wave of the digital isolator. For example, compared to a case where only a planar pattern is provided on the path (that is, only the capacitor is provided), it is possible to adjust the pass band according to the frequency of the carrier wave. Therefore, in the substrate on which the digital isolator is to be mounted, since the common mode current is less likely to be diffused as radiation noise (emission), occurrence of electro magnetic interference can be suppressed.

(Technique 2) The substrate according to technique 1, in which the two planar patterns of the plurality of planar patterns are: a first planar pattern connected to the first ground layer; and a second planar pattern connected to the second power supply layer.

According to this, since the first ground layer is formed on the first principal surface and the second power supply layer is formed on the second principal surface, a capacitor can be configured with a simple configuration.

(Technique 3) The substrate according to technique 2, in which the linear pattern connects: i) between the first planar pattern and the first ground layer; or ii) between the second planar pattern and the second power supply layer.

According to this, since the resonance frequency of the LC series resonant circuit provided between the first ground layer and the second power supply layer can be adjusted, it is possible to adjust the pass band according to the frequency of the carrier wave in the path, and it is possible to suppress occurrence of electro magnetic interference.

(Technique 4) The substrate according to technique 1, in which the two planar patterns of the plurality of planar patterns are: a first planar pattern connected to the first ground layer; and a second planar pattern connected to the second ground layer.

According to this, it is possible to form the feedback path of the common mode current by the path between the first ground layer and the second ground layer.

(Technique 5) The substrate according to technique 4, in which the linear pattern connects: i) between the first planar pattern and the first ground layer; or ii) between the second planar pattern and the second ground layer.

According to this, since the resonance frequency of the LC series resonant circuit provided between the first ground layer and the second ground layer can be adjusted, it is possible to adjust the pass band according to the frequency of the carrier wave in the path, and it is possible to suppress occurrence of electro magnetic interference.

(Technique 6) The substrate according to technique 5, in which the core layer is provided with a through hole penetrating from the first principal surface to the second principal surface, the first planar pattern is formed on the second principal surface, and the linear pattern connects the first planar pattern and the first ground layer via the through hole.

According to this, the path between the first ground layer and the second ground layer can be formed by the configuration including the through hole.

(Technique 7) The substrate according to technique 1, in which the two planar patterns of the plurality of planar patterns are: a first planar pattern connected to the first power supply layer; and a second planar pattern connected to the second power supply layer.

According to this, it is possible to form the feedback path of the common mode current by the path between the first power supply layer and the second power supply layer.

(Technique 8) The substrate according to technique 7, in which the linear pattern connects: i) between the first planar pattern and the first power supply layer; or ii) between the second planar pattern and the second power supply layer.

According to this, since the resonance frequency of the LC series resonant circuit provided between the first ground layer and the second power supply layer can be adjusted, it is possible to adjust the pass band according to the frequency of the carrier wave in the path, and it is possible to suppress occurrence of electro magnetic interference.

(Technique 9) The substrate according to technique 1, in which the plurality of planar patterns further includes a third planar pattern and a fourth planar pattern, the two planar patterns of the plurality of planar patterns are: a first planar pattern connected to one layer of the first ground layer and the first power supply layer; and a second planar pattern connected to one layer of the second ground layer and the second power supply layer, at least a part of the third planar pattern is provided to overlap the first planar pattern in the plan view, at least a part of the fourth planar pattern is provided to overlap the second planar pattern in the plan view, and the linear pattern connects between the third planar pattern and the fourth planar pattern.

According to this, since two capacitors are formed, the withstand voltage of the multilayer substrate can be improved.

(Technique 10) The substrate according to any one of technique 1 to 9, in which the resonance frequency of the resonance circuit is set to allow passage of a signal having a frequency of a carrier wave used in the digital isolator.

According to this, since the common mode current can be more reliably fed back to the voltage region of the signal source by the LC resonance circuit having the pass band corresponding to the frequency of the carrier wave, it is possible to suppress more reliably occurrence of electro magnetic interference.

(Technique 11) The substrate according to any one of technique 1 to 10, further including: a first insulating layer stacked on the first principal surface of the core layer and having a conductor layer in each of the first voltage region and the second voltage region; and a second insulating layer stacked on the second principal surface of the core layer and having a conductor layer in each of the first voltage region and the second voltage region.

According to this, since the two pieces of capacitance function as double insulation, the voltage resistance of the multilayer substrate can be improved.

(Technique 12) The substrate according to any one of technique 1 to 11, further including the digital isolator.

According to this, it is possible to suppress occurrence of electro magnetic interference in the substrate on which the digital isolator is mounted.

### INDUSTRIAL APPLICABILITY

The present disclosure is useful for a substrate or the like on which a digital isolator is to be mounted as an insulating device.

### REFERENCE MARKS IN THE DRAWINGS

100, 100a, 100b: multilayer substrate (substrate)
100c: double-sided substrate (substrate)
101: core layer
102: first insulating layer
103: second insulating layer
107: insulating device (digital isolator)
110: first conductor layer
111, 141: first conductor pattern
111a, 121c: third terminal
112, 142: second conductor pattern
112a, 122c: fourth terminal
120: second conductor layer
121, 121a, 121b: first ground layer
122, 122a, 122b: second ground layer
123, 125, 126, 127, 133, 134, 135, 137: planar pattern
124, 136, 138: linear pattern
130: third conductor layer
131, 131a, 131b: first power supply layer
131a1, 132a1, 132b1: recess
132, 132a, 132b: second power supply layer
139: land
140: fourth conductor layer
150: through hole
D1, D2, D3, D4, D5, D6, D7, D8, D9, D10, D11: distance
R1: first voltage region
R2: second voltage region
R3: insulating region

1. A substrate including a first voltage region and a second voltage region in a plan view, and on which a digital isolator is to be mounted to electrically isolate the first voltage region and the second voltage region from each other, the substrate comprising:
a core layer;
a first ground layer that is a conductor and is provided on a first principal surface of the core layer in the first voltage region;
a second ground layer that is a conductor and is provided on the first principal surface of the core layer in the second voltage region;
a first power supply layer provided on a second principal surface of the core layer in the first voltage region;
a second power supply layer provided on the second principal surface of the core layer in the second voltage region;
a plurality of planar patterns that are conductors and include two planar patterns at least partially overlapping each other in the plan view of the substrate; and
a linear pattern that is linear in the plan view, wherein
the linear pattern is provided on a path connecting one of the first ground layer and the first power supply layer and one of the second ground layer and the second power supply layer,
the linear pattern is connected to one of the two planar patterns, and
a resonance frequency of a resonance circuit including the two planar patterns and the linear pattern has a value corresponding to signal transmission by the digital isolator.

2. The substrate according to claim 1, wherein
the two planar patterns of the plurality of planar patterns are:
a first planar pattern connected to the first ground layer; and
a second planar pattern connected to the second power supply layer.

3. The substrate according to claim 2, wherein
the linear pattern connects:
i) between the first planar pattern and the first ground layer;
or
ii) between the second planar pattern and the second power supply layer.

4. The substrate according to claim 1, wherein
the two planar patterns of the plurality of planar patterns are:
a first planar pattern connected to the first ground layer; and
a second planar pattern connected to the second ground layer.

5. The substrate according to claim 4, wherein
the linear pattern connects:
i) between the first planar pattern and the first ground layer;
or
ii) between the second planar pattern and the second ground layer.

6. The substrate according to claim 5, wherein
the core layer is provided with a through hole penetrating from the first principal surface to the second principal surface,
the first planar pattern is formed on the second principal surface, and
the linear pattern connects the first planar pattern and the first ground layer via the through hole.

7. The substrate according to claim 1, wherein
the two planar patterns of the plurality of planar patterns are:
a first planar pattern connected to the first power supply layer; and
a second planar pattern connected to the second power supply layer.

8. The substrate according to claim 7, wherein
the linear pattern connects:
i) between the first planar pattern and the first power supply layer;
or
ii) between the second planar pattern and the second power supply layer.

9. The substrate according to claim 1, wherein
the plurality of planar patterns further includes a third planar pattern and a fourth planar pattern,
the two planar patterns of the plurality of planar patterns are:
a first planar pattern connected to one layer of the first ground layer and the first power supply layer; and
a second planar pattern connected to one layer of the second ground layer and the second power supply layer,
at least a part of the third planar pattern is provided to overlap the first planar pattern in the plan view,
at least a part of the fourth planar pattern is provided to overlap the second planar pattern in the plan view, and
the linear pattern connects between the third planar pattern and the fourth planar pattern.

10. The substrate according to claim 1, wherein
the resonance frequency of the resonance circuit is set to allow passage of a signal having a frequency of a carrier wave used in the digital isolator.

11. The substrate according to claim 1, further comprising:
a first insulating layer stacked on the first principal surface of the core layer and having a conductor layer in each of the first voltage region and the second voltage region; and
a second insulating layer stacked on the second principal surface of the core layer and having a conductor layer in each of the first voltage region and the second voltage region.

12. The substrate according to claim 1, further comprising the digital isolator.
